(19) United States
(12) Patent Application Publication
(10) Pub. No.: US 2011/0143168 A1
(43) Pub. Date: Jun. 16, 2011

(54) CO-FE ALLOY FOR SOFT MAGNETIC FILMS, SOFT MAGNETIC FILM, AND PERPENDICULAR MAGNETIC RECORDING MEDIUM

(75) Inventors: Tomonori Ueno, Yasugi (JP); Jun Fukuoka, Yasugi (JP); Hide Ueno, Yasugi (JP); Mitsuharu Fujimoto, Yasugi (JP)

(73) Assignee: HITACHI METALS, LTD., Minato-ku, Tokyo (JP)

(21) Appl. No.: 13/058,119

(22) PCT Filed: Oct. 30, 2009
(86) PCT No.: PCT/JP2009/068652

§ 371 Date: Feb. 8, 2011

(30) Foreign Application Priority Data
Nov. 5, 2008 (JP) 2008-284284
Sep. 24, 2009 (JP) 2009-219776

(51) Int. Cl. G11B 5/667; C23C 14/14; C22C 19/07

(52) U.S. Cl. 428/832; 204/298.13; 420/435

(57) ABSTRACT

Disclosed is a Co—Fe alloy for soft magnetic films used in perpendicular magnetic recording media, etc., which maintains high soft magnetic properties and has excellent weather resistance. Disclosed is a Co—Fe alloy for soft magnetic films, which is a Co—Fe alloy the composition formula of which is expressed at atomic ratio as ((Co_{100-X}—Fe_{X})_{100-Y}—Ni_{Y})_{100-(a+b+c)}-Mlₐ-M2_{b}-Ti_{c}, where 5≦X≦80, 0≦Y≦25, 2≦a≦6, 2≦b≦10, and 0.5≦c≦10, the remainder of which is composed of unavoidable impurities, and wherein the element M1 in the aforementioned composition formula is one or two or more elements selected from (Zr, Hf, Y), and the element M2 in the aforementioned composition formula is one or two or more elements selected from (Ta, Nb).

### TECHNICAL FIELD

The present invention relates to a Co—Fe based alloy for a soft magnetic film, the soft magnetic film, and a perpendicular magnetic recording medium including the soft magnetic film.

### BACKGROUND ART

Recently, much progress has been made in magnetic recording techniques, and high recording density of magnetic recording medium has been pursued since a capacity of a drive is increasing. However, in magnetic recording medium of widely used longitudinal magnetic recording system, an attempt to achieve the high recording density leads to a refined recording bit which requires such a high coercive force that recording cannot be made with a recording head. To solve the problem, a perpendicular magnetic recording system has been studied as a measure to improve the recording density.

In the perpendicular magnetic recording system, a perpendicular magnetic recording medium has a magnetic film, and an axis of easy magnetization is oriented perpendicularly to a medium surface. The system is suitable for high recording density since it has a small demagnetizing field in a bit and a small decrease in the read/write characteristics even if the recording density is increased. For the perpendicular magnetic recording system, the recording medium having the magnetic recording film layer with an increased recording sensitivity and a soft magnetic film layer has been developed.

The soft magnetic film for such magnetic recording medium needs to have a high saturation magnetic flux density, and a Co—Fe alloy has been suitably used since it has a high saturation magnetic flux density. Particularly, an amorphous film is desired as the soft magnetic film for the magnetic recording medium since it has excellent soft magnetic properties. Thus, it is necessary to add an element which facilitates amorphization to the Co—Fe alloy. For the element, Zr or Ta is generally employed.

The soft magnetic film is generally produced through a magnetron sputtering process with use of a target material of the same composition. On the other hand, since such a Co—Fe based alloy target material has the problem of weatherability, proposed is a target material including the Co—Fe based alloy added with Al or Cr (see, for example, Patent Document 1).
Patent Document 1: JP-A-2007-284741

### SUMMARY OF THE INVENTION

A target material for a soft magnetic film disclosed in the Patent Document 1 is effective since a certain improvement in weatherability is achieved by adding 0.2 to 5 atomic % of Al or Cr to a Co—Fe alloy. However, studies of the present inventors have proved that sufficient weatherability can not be obtained by the addition of Al or Cr.

An object of the present invention is to solve the above problems and to provide a Co—Fe based alloy for a soft magnetic film used in a perpendicular magnetic recording medium or the like, which has excellent weatherability while maintaining high soft magnetic properties.

The present inventors have conducted intensive studies on an element to be added to the Co—Fe based alloy for a soft magnetic film used in a perpendicular magnetic recording medium or the like. As a result, they have found addition of Ti and its suitable range of the addition of Ti. Thus, the present invention has been accomplished.

Accordingly, the present invention provides a Co—Fe based alloy for a soft magnetic film, having a composition represented by a formula by an atomic ratio:

((Co_{100-X}—Fe_{X})_{100-Y}—Ni_{Y})_{100-(a+b+c)}-M1ₐ-M2_{b}-Ti_{c},

where 5≦X≦80, 0≦Y≦25, 2≦a≦6, 2≦b≦10, 0.5≦c≦10, and the balance being unavoidable impurities, wherein the M1 element in the formula is one or more elements selected from Zr, Hf and yttrium, and the M2 element in the formula is one or more elements selected from Ta and Nb. The Co—Fe based alloy for a soft magnetic film of the present invention may contain not more than 5 atomic % of boron (B).

The Co—Fe based alloy for a soft magnetic film of the present invention may be applied to a sputtering target material or a soft magnetic film layer in a perpendicular magnetic recording medium. Furthermore, the Co—Fe based alloy preferably has a saturation magnetization of not lower than 1.0 T.

According to the present invention, a Co—Fe based alloy for a soft magnetic film used in a perpendicular magnetic recording medium or the like is provided, which has excellent weatherability while maintaining high soft magnetic properties. It is very advantageous for manufacturing the perpendicular magnetic recording medium.

### DETAIL DESCRIPTION OF THE INVENTION

It is important that the present invention selects Ti as a most suitable element for effectively improving weatherability without a significant decrease in the soft magnetic properties in a Co—Fe based alloy for a soft magnetic film, and also it finds the amount to be added for achieving the above advantage.

First, the Co—Fe based alloy which serves as a basis for the present invention will be described below.

A Co—Fe alloy which is a base of the Co—Fe based alloy of the present invention has a composition represented by (Co_{100-X}—Fe_{X})_{100-Y}—Ni_{Y}), where 5≦X≦80 and 0≦Y≦25. The Co—Fe alloy having a composition within the range has a high saturation magnetization and thus is suitable for a soft magnetic film. A part of the Co—Fe alloy may be substituted by Ni to an extent 0≦Y≦25. This is because the soft magnetic properties can be effectively improved without a significant decrease in the saturation magnetization.

2 to 6 atomic % of one or more elements selected from Zr, Hf and yttrium is added to the above Co—Fe alloy as an M1 element, and 2 to 10 atomic % of one or more elements selected from Ta and Nb is added thereto as an M2 element. This is because adding of the M1 and M2 elements in the above range facilitates amorphization and improves magnetic characteristics as a sputtering film without a significant decrease in the saturation magnetization of the Co—Fe alloy.

The Co—Fe based alloy of the present invention contains 0.5 to 10 atomic % of Ti as an essential element for effectively improving the weatherability of the Co—Fe based alloy. A potential/pH diagram shows that Ti has a passivation region in a broad pH range, and thus Ti is selected as an element to be added effective in improving the weatherability. The above advantage of improving the weatherability is small when the content of Ti is less than 0.5 atomic %, and the magnetization is decreased when the content of Ti is more than 10 atomic %. Thus, it is important to control the content of Ti in a range of 0.5 to 10 atomic %. Furthermore, the content of Ti is desirably not more than 5 atomic % to prevent decreasing of the magnetization.

As described above, the Co—Fe based alloy of the present invention has a composition represented by the formula by an atomic ratio: ((Co_{100-X}—Fe_{X})_{100-Y}—Ni_{Y})_{100-(a+b+c)}-M1ₐM2_{b}-Ti_{c}, where 5≦X≦80, 0≦Y≦25, 2≦a≦6, 2≦b≦10, and 0.5≦c≦10. The Co—Fe based alloy may contain unavoidable impurities without deteriorating the advantages of the present invention. For example, the Co—Fe based alloy represented by the formula may have a purity of not lower than 99.9%.

The Co—Fe based alloy of the present invention may further contain not more than 5 atomic % of boron. The addition of not more than 5 atomic % of boron can improve mechanical properties of the alloy, in particular hardness, without a significant decrease in the weatherability or magnetization.

A process for producing the Co—Fe based alloy may include a melt casting process or a powder sintering process. In the melt casting process, the Co—Fe based alloy may be produced in a form of a cast ingot or a bulk which is obtained by plastic working or pressing of the cast ingot. In the powder sintering process, a Co—Fe based alloy powder of a final composition may be produced, by a gas atomizing process, to be used as a raw material powder. Alternatively, a mixed powder may be obtained by mixing a plurality of alloy powders or pure metal powders to form the final composition of the Co—Fe based alloy as raw material powder. A process of sintering the raw material powder may include pressure sintering such as hot isostatic pressing, hot pressing, spark plasma sintering or extrusion press sintering.

The Co—Fe based alloy of the present invention may be processed in a target material suitable for various types of sputtering apparatus to form a soft magnetic film having excellent weatherability by sputtering the target.

### Example 1

The present invention will be described in more detail by means of Examples.

First, cast ingots having Co—Fe based alloy compositions shown in Table 1 were produced. Raw materials having a purity of not less than 99.9% were heated and melted in a high-frequency heating furnace under vacuum and the molten alloys were cast in a mold made of iron to form the ingots having a diameter of 220 mm×45 mm. The resulting ingots were processed into Co—Fe based alloy bulks having a diameter of 180 mm and a thickness of 7 mm.

For evaluating the weatherability of the bulks, samples having a diameter of 10 mm×20 mm were produced from the cast ingots and dipped in 10% hydrochloric acid at 50° C. for 24 hours. The weight reduction rates were measured to evaluate the weatherability of the bulks. The measurement results are shown in Table 1.

For evaluating the magnetization of the bulks, samples of 30 mm×10 mm×5 mm were produced from the cast ingots, and the magnetization under an external magnetic field of 160 kA/m was measured using a DC magnetic properties measurement apparatus (TRF5A made by Toei Industry Co., Ltd.). The results are shown in Table 2.

TABLE 1

| | | Weight | |
|---|---|---|---|
| | | reduction | |
| Sam- | Composition of Co—Fe based alloy | rate | |
| ple | (atomic %) | (%) | Remarks |
| 1 | (Co₇₀—Fe₃₀)₉₀—Zr₄—Ta₄—Ti₂ | 0.2 | Present |
| | | | invention |
| 2 | (Co₇₀—Fe₃₀)₉₀—Zr₄—Ta₄—Al₁—Cr₁ | 1.3 | Comparative |
| | | | Example |
| 3 | (Co₇₀—Fe₃₀)₉₂—Zr₄—Ta₄ | 0.5 | Comparative |
| | | | Example |

TABLE 2

| | | Magnet- | |
|---|---|---|---|
| Sam- | Composition of Co—Fe based alloy | ization | |
| ple | (atomic %) | (T) | Remarks |
| 1 | (Co₇₀—Fe₃₀)₉₀—Zr₄—Ta₄—Ti₂ | 1.3 | Present |
| | | | invention |
| 2 | (Co₇₀—Fe₃₀)₉₀—Zr₄—Ta₄—Al₁—Cr₁ | 1.3 | Comparative |
| | | | Example |
| 3 | (Co₇₀—Fe₃₀)₉₂—Zr₄—Ta₄ | 1.4 | Comparative |
| | | | Example |

Table 1 shows that the Co—Fe based alloy of the present invention containing 0.5 to 10 atomic % of Ti (sample 1) has a higher weatherability than the Co—Fe based alloy without Ti (sample 3) or the Co—Fe based alloy with Al and Cr (sample 2). Table 2 shows that the bulks of sample 1 of the present invention and sample 2 of the Co—Fe based alloy containing Al and Cr have a nearly equal magnetization. The Co—Fe based alloy of the sample 1 is available for a target material or a soft magnetic film having excellent weatherability.

### Example 2

First, cast ingots having Co—Fe based alloy compositions shown in Table 3 were produced. Raw materials having a purity of not less than 99.9% were heated and melted in a high-frequency heating furnace under vacuum and the molten alloys were cast in a mold made of iron to form the ingots having a diameter of 200 mm×25 mm. The resulting ingots were processed into Co—Fe based alloy bulks having a diameter of 180 mm and a thickness of 7 mm.

For evaluating the weatherability of the bulks, samples having a diameter of 10 mm×20 mm were produced from the cast ingots and dipped in 10% sulfuric acid at 50° C. for 24 hours, and the weight reduction rates were measured to evaluate the weatherability of the bulks. The measurement results are shown in Table 3.

For evaluating the magnetization of the bulks, samples of 30 mm×10 mm×5 mm were produced from the cast ingots, and the magnetization under an external magnetic field of 160 kA/m was measured using a DC magnetic properties measurement apparatus (TRF5A made by Toei Industry Co., Ltd.). The results are shown in Table 4.

For evaluating the hardness of the bulks, 10 mm×10 mm×5 mm samples were produced from the cast ingots and the hardness was measured using Rockwell hardness tester on C scale. The results are shown in Table 5.

TABLE 3

| | | Weight | |
|---|---|---|---|
| | | reduc- | |
| | | tion | |
| Sam- | Composition of Co—Fe based alloy | rate | |
| ple | (atomic %) | (%) | Remarks |
| 4 | (Co₇₀—Fe₃₀)₉₀—Zr₄—Ta₄—Ti₁—B₁ | 6.9 | Present |
| | | | invention |
| 5 | (Co₇₀—Fe₃₀)₉₀—Zr₄—Ta₄—Ti₂ | 7.9 | Present |
| | | | invention |
| 6 | ((Co₅₃—Fe₄₇)₉₅—Ni₅)₈₈—Zr₂—Nb₆—Ti₄ | 9.7 | Present |
| | | | invention |
| 7 | (Co₇₀—Fe₃₀)₉₀—Zr₄—Ta₄—Al₂ | 10.3 | Com- |
| | | | parative |
| | | | Example |
| 8 | (Co₇₀—Fe₃₀)₉₀—Zr₄—Ta₄—Cr₂ | 10.8 | Com- |
| | | | parative |
| | | | Example |

TABLE 4

| | | Magnet- | |
|---|---|---|---|
| Sam- | Composition of Co—Fe based alloy | ization | |
| ple | (atomic %) | (T) | Remarks |
| 4 | (Co₇₀—Fe₃₀)₉₀—Zr₄—Ta₄—Ti₁—B₁ | 1.3 | Present |
| | | | invention |
| 5 | (Co₇₀—Fe₃₀)₉₀—Zr₄—Ta₄—Ti₂ | 1.3 | Present |
| | | | invention |
| 6 | ((Co₅₃—Fe₄₇)₉₅—Ni₅)₈₈—Zr₂—Nb₆—Ti₄ | 1.1 | Present |
| | | | invention |
| 7 | (Co₇₀—Fe₃₀)₉₀—Zr₄—Ta₄—Al₂ | 1.3 | Com- |
| | | | parative |
| | | | Example |
| 8 | (Co₇₀—Fe₃₀)₉₀—Zr₄—Ta₄—Cr₂ | 1.3 | Com- |
| | | | parative |
| | | | Example |

TABLE 5

| Sam- | Composition of Co—Fe based alloy | Hardness | |
|---|---|---|---|
| ple | (atomic %) | (H_{RC}) | Remarks |
| 4 | (Co₇₀—Fe₃₀)₉₀—Zr₄—Ta₄—Ti₁—B₁ | 59.1 | Present |
| | | | invention |
| 5 | (Co₇₀—Fe₃₀)₉₀—Zr₄—Ta₄—Ti₂ | 56.8 | Present |
| | | | invention |
| 6 | ((Co₅₃—Fe₄₇)₉₅—Ni₅)₈₈—Zr₂—Nb₆—Ti₄ | 59.6 | Present |
| | | | invention |
| 7 | (Co₇₀—Fe₃₀)₉₀—Zr₄—Ta₄—Al₂ | 55.0 | Com- |
| | | | parative |
| | | | Example |
| 8 | (Co₇₀—Fe₃₀)₉₀—Zr₄—Ta₄—Cr₂ | 48.2 | Com- |
| | | | parative |
| | | | Example |

Table 3 shows that the Co—Fe based alloys of the present invention containing 0.5 to 10 atomic % of Ti (samples 4, 5 and 6) have a higher weatherability than the Co—Fe based alloys with Al or Cr (samples 7 and 8). Table 4 shows that the bulks of samples 4, 5 and 6 of the present invention and samples 7 and 8 of the Co—Fe based alloys containing Al or Cr have a nearly equal magnetization. Further, Table 5 shows that the Co—Fe based alloy of the present invention containing 0.5 to 10 atomic % of Ti and not more than 5 atomic % of B (sample 4) has improved hardness.

### Example 3

First, cast ingots having Co—Fe based alloy compositions shown in Table 6 were produces. Raw materials having a purity of not less than 99.9% were heated and melted in a high-frequency heating furnace under vacuum and cast in a mold made of iron to form the ingots having a diameter of 200 mm×25 mm. The resulting ingots were processed into Co—Fe based alloy target materials having a diameter of 180 mm and a thickness of 7 mm.

The produced target materials were used in a magnetron sputtering process to form a Co—Fe based alloy thin film on a substrate for the following evaluation tests. The sputtering process was carried out under conditions of an Ar pressure of 0.6 Pa and an input electric power of 500 W.

### (1) Weatherability Test

Thin film samples deposited on glass substrates having a film thickness of 200 nm were subjected to a weatherability test involving dipping them in pure water for 24 hours. The results of the visual observation of corroded regions are shown in Table 6. In Table 6, a sample in which no corroded region is visually observed is described as “◯” and a sample in which a corroded region is visually observed is described as “x”.

### (2) Evaluation of Magnetization

Thin film samples formed on a silicon wafer in a film thickness of 300 nm were cut into 10×10 mm and subjected to the evaluation of the saturation magnetization. The results are shown in Table 6. The measurement was carried out using a vibrating sample magnetometer VSM-3 made by Toei Industry Co., Ltd. under an external magnetic field of 800,000 A/m.

### (3) Evaluation of Hardness

Thin films were formed on aluminum substrates having a film thickness of 4 μm. The results of measuring the hardness of the samples are shown in Table 6. The hardness was measured at five points at an applied load of 25 g using a Micro-Vickers apparatus. The average value is determined as hardness and shown in Table 6.

TABLE 6

| | | Weather- | Magnet- | | |
|---|---|---|---|---|---|
| | Composition of Co—Fe based alloy | ability | ization | Hardness | |
| Sample | (atomic %) | test | (T) | (Hv) | Remarks |
| 9 | (Co₇₀—Fe₃₀)₉₀—Zr₄—Ta₄—Ti₂ | ◯ | 1.4 | 785 | Present |
| | | | | | inven- |
| | | | | | tion |
| 10 | (Co₇₀—Fe₃₀)₉₀—Zr₄—Ta₄—Al₁—Cr₁ | X | 1.4 | 655 | Compar- |
| | | | | | ative |
| | | | | | Example |

Table 6 proves that the Co—Fe based alloy of the present invention containing 0.5 to 10 atomic % of Ti has excellent weatherability even when formed into a thin film by the sputtering process.

### INDUSTRIAL APPLICABILITY

The Co—Fe based alloy for a soft magnetic film of the present invention has excellent weatherability while maintaining soft magnetic properties, and therefore can be used for forming a soft magnetic film for a perpendicular magnetic recording medium or the like under stable conditions.

1. A Co—Fe based alloy for a soft magnetic film, having a composition represented by a formula by an atomic ratio:
((Co_{100-X}—Fe_{X})_{100-Y}—Ni_{Y})_{100-(a+b+c)}-M1ₐ-M2_{b}-Ti_{c},
where 5≦X≦80, 0≦Y≦25, 0.5≦c≦10, and the balance being unavoidable impurities,
wherein the M1 element in the formula is one or more elements selected from Zr, Hf and yttrium and the M2 element in the formula is one or more elements selected from Ta and Nb.

2. The Co—Fe based alloy according to claim 1, further comprising boron (B) and has a composition represented by a formula, by an atomic ratio:
((Co_{100-X}—Fe_{X})_{100-Y}—Ni_{Y})_{100-(a+b+c+d)}-M1ₐ-M2_{b}-Ti_{c}—B_{d},
where 5≦X≦80, 0≦Y≦25, 2≦a≦6, 2≦b≦10, 0.5≦c≦10, d≦5, and the balance being unavoidable impurities.

3-4. (canceled)

5. The Co—Fe based alloy according to claim 1, wherein the Co—Fe based alloy has saturation magnetization of not lower than 1.0 T.

6. A soft magnetic film made of the Co—Fe based alloy according to claim 1 and formed by a sputtering process.

7. A perpendicular magnetic recording medium, comprising:
a magnetic recording film layer; and
at least one layer of soft magnetic film made of the Co—Fe based alloy according to claim 1 as an underlayer of the magnetic recording film layer.

8. The perpendicular magnetic recording medium according to claim 7, wherein the at least one layer is formed by a sputtering process.

9. A sputtering target made of the Co—Fe based alloy according to claim 1.
